(19) United States
(12) Patent Application Publication
(10) Pub. No.: US 2006/0148175 A1
(43) Pub. Date: Jul. 6, 2006

(54) Method of manufacturing a flash memory device

(75) Inventors: Dong-Oog Kim, Yongsan-ku (KR); Chang-Hun Han, Icheon-city (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Kangnam-ku (KR)

(21) Appl. No.: 11/320,586

(22) Filed: Dec. 30, 2005

(30) Foreign Application Priority Data
Dec. 30, 2004 (KR) 10-2004-0117162

(51) Int. Cl. H01L 21/336

(52) U.S. Cl. 438/264; 438/266

(57) ABSTRACT

A method of manufacturing a semiconductor device includes forming a polysilicon layer on a trench isolation layer and a tunnel oxide layer formed on a semiconductor substrate, and doping the polysilicon layer with germanium or argon. The doped polysilicon layer is patterned to form a floating gate electrode layer pattern. A charge-trapping layer is formed on the floating gate electrode layer pattern, and a control gate electrode layer pattern is formed on the charge-trapping layer.

### BACKGROUND OF THE INVENTION

(a) Field of the Invention

The present invention relates to a semiconductor device such as a flash memory device, and more particularly to a method of manufacturing the flash memory device having a dual gate structure.

(b) Discussion of the Related Art

Generally, a flash memory device, such as an ETOX (EEPROM Tunnel Oxide) device, has a dual gate structure including a floating gate and a control gate. Characteristics of the flash memory device are determined by an erasing operation and a program operation.

When a predetermined voltage is applied to the control gate, the flash memory device having the dual gate structure can have a voltage applied at the floating gate through a dielectric layer by using a coupling ratio. To increase the coupling ratio, the floating gate is formed by using a polysilicon layer, such as an amorphous polysilicon layer, doped with phosphorus.

FIGS. 1-6 are cross-sectional views showing sequential stages of a conventional method of manufacturing a flash memory device.

As shown in FIG. 1, a hard mask layer is sequentially accumulated on a semiconductor substrate 100. The hard mask layer is formed in a structure including a pad oxide layer 110, a nitride layer 120, and an oxide layer 130, sequentially accumulated on one another. The upper oxide layer 130 is formed from a TEOS (tetraethoxysilane) oxide layer. Subsequently, a photoresist layer pattern 140 is formed on the oxide layer 130. The photoresist layer pattern 140 defines openings 141 exposing a portion of a surface of the oxide layer 130 in the region where an isolation layer will be formed.

FIG. 2 shows that hard mask layer patterns (111, 121, and 131) are formed by sequentially etching the oxide layer 130, the nitride layer 120, and the pad oxide layer 110 using the photoresist layer pattern 140 as an etch mask. The hard mask layer patterns are formed in a structure including a pad oxide layer pattern 111, a nitride layer pattern 121, and an oxide layer pattern 131, sequentially accumulated on one another. After forming the hard mask layer pattern, the photoresist layer pattern 140 is removed. A trench 101 is formed by etching an exposed surface of the semiconductor substrate 100 to a predetermined depth using the hard mask layer patterns 111, 121, and 131 as etch masks.

As shown in FIG. 3, a fill insulation layer 150 is formed to fill the trench 101. The fill insulation layer 150 can be formed of HDP-USG (High Density Plasma-Undoped Silicate Glass).

As shown in FIG. 4, after forming a trench isolation layer 151 by performing a planarization process, the oxide layer pattern 131 and nitride layer pattern 121 are removed. Active regions are defined by the trench isolation layer 151.

FIG. 5 shows a polysilicon layer 161, which is used for forming a floating gate electrode layer, formed on the trench isolation layer 151 and pad oxide layer pattern 111. The polysilicon layer 161 is a polysilicon layer doped with phosphorus.

As shown in FIG. 6, a polysilicon layer pattern 163, which is used for forming a floating gate electrode layer, is formed by patterning the polysilicon layer 161. In addition, an ONO layer 170 is formed on the polysilicon layer pattern 163, and then a polysilicon layer 180 for forming a control gate electrode layer is formed on the ONO layer 170.

FIG. 7 is a cross-sectional view showing another conventional method of manufacturing a flash memory device. As shown in FIG. 7, after performing the same processes shown in FIGS. 1-4, a polysilicon layer 162, which is used for forming a floating gate electrode layer, is formed on the trench isolation layer 151 and pad oxide layer pattern 111.

The polysilicon layer 162 is an amorphous polysilicon layer. Subsequently, phosphorus (P) is doped into the polysilicon layer 162 such that the polysilicon layer 162 has conductivity. Thereafter, the same processes as shown in FIG. 6 are performed.

However, there is a limit to the amount by which the coupling ratio of the flash memory device can be increased, when the device is produced by the above discussed conventional methods. The increase in the coupling ratio is limited by the amount that the surface area of the polysilicon layer pattern 163 used for forming the floating gate electrode layer, as shown in FIG. 6, can be increased. Consequently, the amount of charge trapped at the floating gate is limited.

### SUMMARY OF THE INVENTION

To address the above-described and other problems, it is an object of the present invention to provide a method of manufacturing a semiconductor device. The method includes forming a polysilicon layer on a trench isolation layer and a tunnel oxide layer formed on a semiconductor substrate, and doping the polysilicon layer with germanium or argon. The doped polysilicon layer is patterned to form a floating gate electrode layer pattern. A charge-trapping layer is formed on the floating gate electrode layer pattern, and a control gate electrode layer pattern is formed on the charge-trapping layer.

The present invention further provides a method of manufacturing a memory device, including forming a trench isolation layer on a substrate, forming a tunnel oxide layer on the substrate, and forming a polysilicon layer on the trench isolation layer and the tunnel oxide layer. The polysilicon layer is doped, and the doped polysilicon layer is patterned to form a floating gate electrode layer pattern. A charge-trapping layer is formed on the floating gate electrode layer pattern, and a control gate electrode layer pattern is formed on the charge-trapping layer.

### BRIEF DESCRIPTION OF THE DRAWINGS

The accompanying drawings, which are incorporated in and constitute a part of the specification, illustrate an embodiment of the invention, and together with the description serve to explain principles of the invention.

FIGS. 1-6 are cross-sectional views showing a conventional method of manufacturing a flash memory device.

FIG. 7 is a cross-sectional view showing another conventional method of manufacturing a flash memory device.

FIGS. 8-12 are cross-sectional views showing a method of manufacturing a flash memory device according to an embodiment of the present invention.

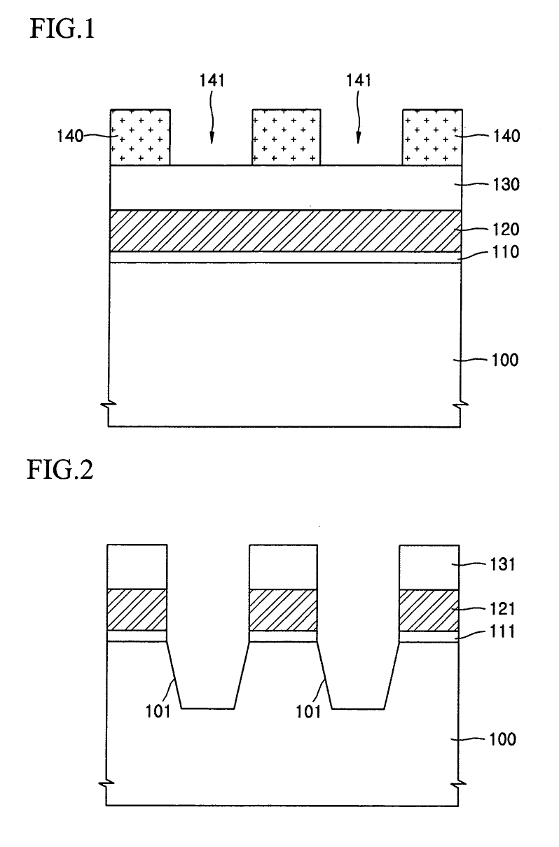

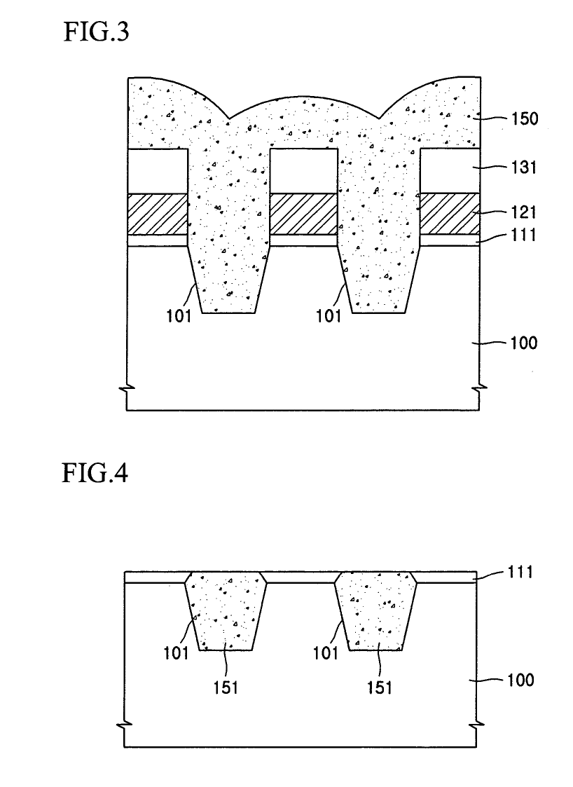

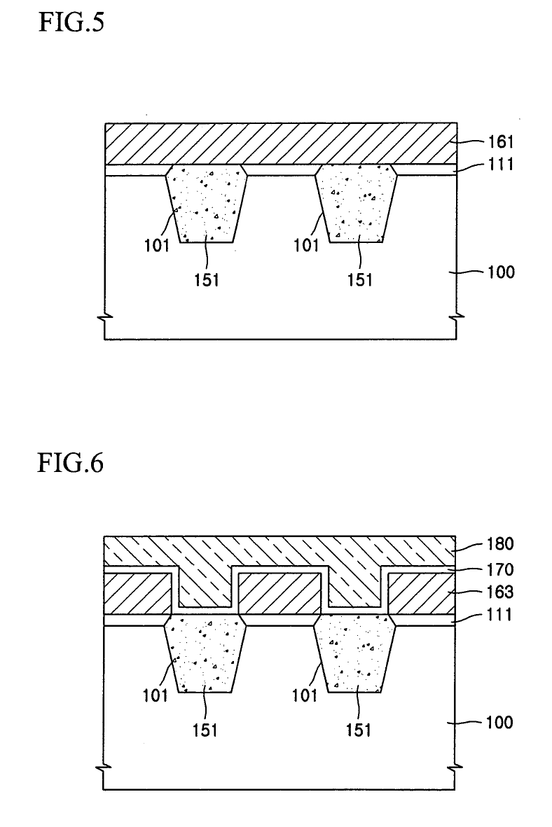

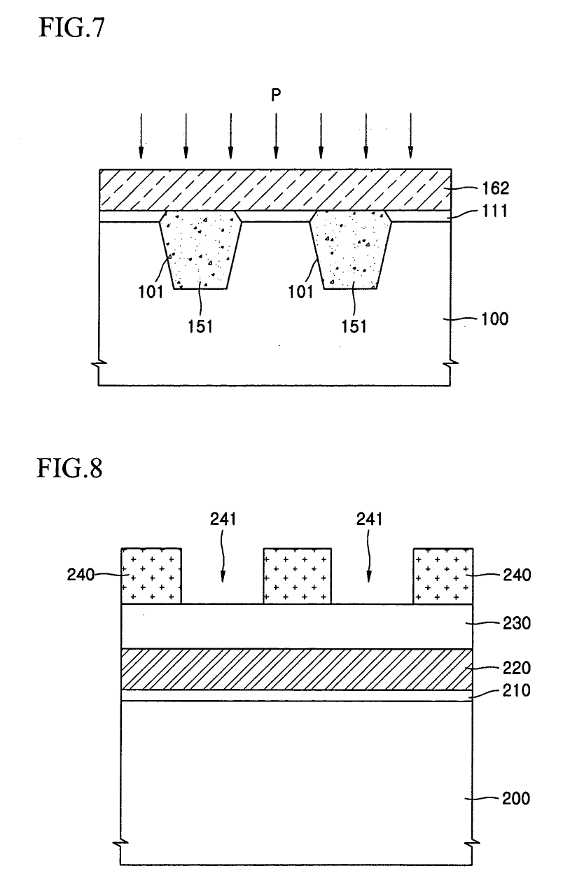

### DETAILED DESCRIPTION OF THE INVENTION

An exemplary embodiment of the present invention is described below with reference to the accompanying drawings.

Thicknesses of the regions and layers shown in the drawings are enlarged to better show features of the invention.

FIGS. 8-12 are cross-sectional views showing a method of manufacturing a flash memory device according to an embodiment of the present invention.

As shown in FIG. 8, hard mask layers (210, 220, and 230) are sequentially accumulated on a semiconductor substrate 200. The hard mask layers include a pad oxide layer 210, a nitride layer 220, and an upper oxide layer 230. The upper oxide layer 230 is formed as a TEOS (tetraethoxysilane) oxide layer.

A photoresist layer pattern 240 is formed on the upper oxide layer 230. The photoresist layer pattern 240 defines openings 241 exposing a portion of a surface of the upper oxide layer 230 in the region where an isolation layer will be formed.

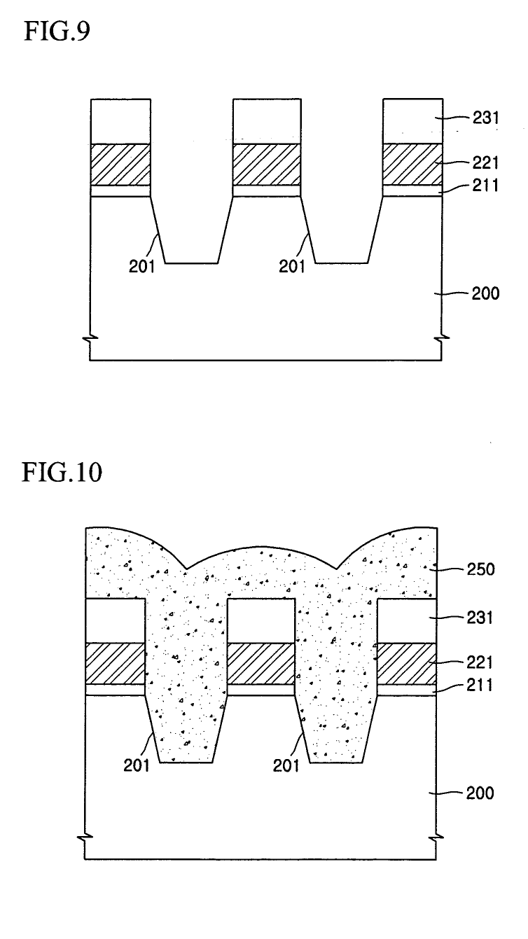

FIG. 9 shows hard mask layer patterns (211, 221, and 231) formed by sequentially etching the upper oxide layer 230, the nitride layer 220, and the pad oxide layer 210 using the photoresist layer pattern 240 as an etch mask. The hard mask layer patterns include a pad oxide layer pattern 211, a nitride layer pattern 221, and an upper oxide layer pattern 231.

After forming the hard mask layer pattern, the photoresist layer pattern 240 is removed. A trench 201 is formed by etching an exposed surface of the semiconductor substrate 200 to a predetermined depth using the hard mask layer patterns (211, 221, and 231) as etch masks.

As shown in FIG. 10, a fill insulation layer 250 is formed to fill in the trench 201. The fill insulation layer 250 can be formed from HDP-USG (High Density Plasma-Undoped Silicate Glass).

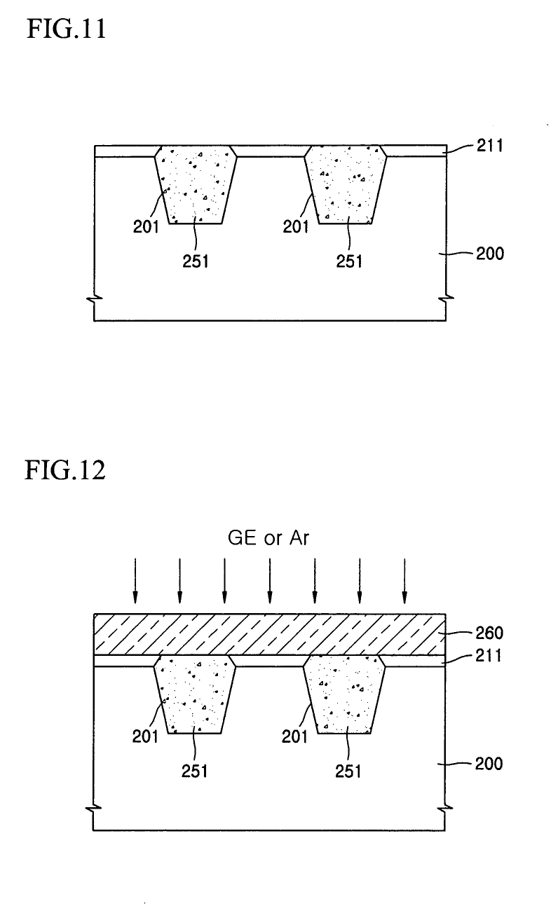

FIG. 11 shows a trench isolation layer 251, which defines active regions on the semiconductor substrate 200, formed by performing a planarization process, and removal of the upper oxide layer pattern 231 and the nitride layer pattern 221. Alternately, a tunnel oxide layer can be formed after removing the pad oxide layer pattern 211. According to the exemplary embodiment of the present invention, the pad oxide layer pattern 211 acts as the tunnel oxide layer.

As shown in FIG. 12, a polysilicon layer 260, which is used to form a floating gate electrode layer, is disposed on the trench isolation layer 251 and the pad oxide layer pattern 211. The polysilicon layer 260 can be an amorphous polysilicon layer. Germanium (Ge) or argon (Ar) can be implanted into the amorphous polysilicon layer 260. Germanium (Ge) has an atomic weight of 72.61, which is about twice the atomic weight of phosphorus (P), which is used as a doped ion in the conventional method of manufacturing a flash memory device.

Doping the amorphous polysilicon layer 260 with either germanium (Ge) or argon (AR) results in roughening of the layer 260, such that the layer 260 has a greater surface area and conductivity. When the amorphous polysilicon layer 260 is doped with germanium (Ge), controlling the ion energy is not required.

Although not shown in the drawings, a polysilicon layer pattern for forming a floating gate electrode layer is provided by patterning the polysilicon layer 260 doped with germanium (Ge) or argon (Ar). An ONO layer, acting as a charge-trapping layer, is formed on the polysilicon layer pattern, and a polysilicon layer for forming a control gate electrode layer is formed on the ONO layer.

As described above, according to the embodiment of the present invention, the amorphous polysilicon layer is formed as the floating gate electrode layer, and the surface of the polysilicon layer is roughened as a result of the doping with germanium (Ge) or argon (Ar). Consequently, the charge-trapping ability of the floating gate electrode layer can be enhanced because of the increase in surface area of the polysilicon layer. Operation characteristics of the device can be enhanced due to an increase of a coupling ratio. In addition, power consumption of the device is also reduced.

The above discussion is directed to a preferred embodiment of the invention. It is to be understood, however, that the invention is not limited to the disclosed embodiment. Rather, the invention is intended to cover various modifications and equivalent arrangements included within the spirit and scope of the appended claims.

The present application claims priority to, and incorporates by reference herein in its entirety, Korean patent application no. 10-2004-0117162, filed on Dec. 30, 2004.

What is claimed is:

1. A method of manufacturing a semiconductor device, comprising:
forming a polysilicon layer on a trench isolation layer and a tunnel oxide layer formed on a semiconductor substrate;
doping the polysilicon layer with germanium or argon;
patterning the doped polysilicon layer to form a floating gate electrode layer pattern;
forming a charge-trapping layer on the floating gate electrode layer pattern; and
forming a control gate electrode layer pattern on the charge-trapping layer.

2. The method according to claim 1, wherein the trench isolation layer defines active regions, and the tunnel oxide layer is formed on the active regions.

3. The method according to claim 2, further comprising:
forming the trench isolation by
forming a hard mask layer pattern including a pad oxide layer pattern, a nitride layer pattern, and an upper oxide layer pattern on the semiconductor substrate;
etching the semiconductor substrate to a predetermined depth using the hard mask layer pattern as an etch mask to form a trench;
depositing a fill insulation layer on an entire surface of the substrate to fill the trench with the insulation layer; and
planarizing the substrate after depositing the fill insulation layer.

4. The method according to claim 3, wherein the upper oxide layer pattern comprises a TEOS oxide layer.

5. The method according to claim 3, wherein the fill insulation layer comprises a HDP-USG (High Density Plasma-Undoped Silicate Glass) layer.

6. The method according to claim 3, further comprising:
removing the pad oxide layer pattern, the upper oxide layer pattern and the nitride layer pattern, after formation of the trench isolation layer, to form the tunnel oxide layer.

7. The method according to claim 1, wherein forming the charge-trapping layer comprises:
sequentially accumulating in a structure a pad oxide layer, a nitride layer, and an upper oxide layer; and
forming the charge-trapping layer in the structure.

8. The method according to claim 1, wherein the polysilicon layer comprises an amorphous polysilicon layer.

9. A method of manufacturing a memory device, comprising:
forming a trench isolation layer on a substrate;
forming a tunnel oxide layer on the substrate;
forming a polysilicon layer on the trench isolation layer and the tunnel oxide layer;
doping the polysilicon layer;
patterning the doped polysilicon layer to form a floating gate electrode layer pattern;
forming a charge-trapping layer on the floating gate electrode layer pattern; and
forming a control gate electrode layer pattern on the charge-trapping layer.

10. The method according to claim 9, wherein forming the trench isolation layer comprises:
forming a hard mask layer pattern including a pad oxide layer pattern, a nitride layer pattern, and an upper oxide layer pattern on the semiconductor substrate;
etching the semiconductor substrate to a predetermined depth using the hard mask layer pattern as an etch mask to form a trench;
depositing a fill insulation layer on an entire surface of the substrate to fill the trench with the insulation layer; and
planarizing the substrate after depositing the fill insulation layer.

11. The method according to claim 10, wherein the upper oxide layer pattern comprises a TEOS oxide layer.

12. The method according to claim 10, wherein the fill insulation layer comprises a HDP-USG (High Density Plasma-Undoped Silicate Glass) layer.

13. The method according to claim 10, further comprising:
removing the pad oxide layer pattern, the upper oxide layer pattern and the nitride layer pattern, after formation of the trench isolation layer, to form the tunnel oxide layer.

14. The method according to claim 10, wherein forming the charge-trapping layer comprises:
sequentially accumulating in a structure a pad oxide layer, a nitride layer, and an upper oxide layer; and
forming the charge-trapping layer in the structure.

15. The method according to claim 10, wherein the polysilicon layer comprises an amorphous polysilicon layer.
